(19) United States
(12) Patent Application Publication
(10) Pub. No.: US 2022/0359184 A1
(43) Pub. Date: Nov. 10, 2022

(54) ION BEAM IRRADIATION APPARATUS

(71) Applicant: Nissin Ion Equipment Co., Ltd., Kyoto (JP)

(72) Inventors: Hiroaki Kai, Shiga (JP); Yuya Uchida, Shiga (JP)

(21) Appl. No.: 17/583,261

(22) Filed: Jan. 25, 2022

(30) Foreign Application Priority Data
May 6, 2021 (JP) 2021-078720

(51) Int. Cl. H01J 49/10

(52) U.S. Cl. CPC H01J 49/10

(57) ABSTRACT

The ion beam irradiation apparatus 10 includes a vacuum vessel 18 having an internal space R where the ion beam IB taken out from the ion source 11 pass in the first direction D1. The vacuum vessel 18 has a recess 22 that brings the internal space R extended in a second direction D2 intersecting the first direction D1 in a portion of the area between the ion source 11 and the mass spectrometer 14.

### CROSS-REFERENCE TO RELATED APPLICATION

This application claims priority from Japanese Patent Application No. JP 2021-78720, filed May 6, 2021 in the Japanese Patent Office, the entire contents of which is incorporated by reference herein in its entirety.

### BACKGROUND

### 1. Field

The present invention relates to an ion beam irradiation apparatus used in a semiconductor manufacturing process or a flat panel display manufacturing process for irradiating an ion beam onto the substrate.

### 2. Description of Related Art

In the semiconductor manufacturing process or the flat panel display manufacturing process, an ion beam irradiating device that irradiates an ion beam on a substrate is used. Generally, an ion beam irradiation apparatus includes an ion source that generates an ion beam from a raw material gas introduced inside, a vacuum chamber that allows the ion beam to pass along a predetermined beam path, and a processing chamber in which a substrate is arranged. A mass spectrometric magnet for deflecting the ion beam and allowing the desired ion to pass is arranged on the beam path. The ion beam taken out from the ion source is mass-separated by a mass spectrometric magnet, and undesired ions are removed and guided to the processing chamber. In the processing chamber, the substrate is irradiated with an ion beam.

Some conventional ion implanters include a graphite liner disposed inside the vessel which forms the beam path. A plurality of grooves is formed on the surface of this liner to trap particles that become contaminants in the ion implanter. That is, this ion implanter can reduce the contaminants that reach the processing chamber by trapping the particles in the grooves of the liner, and thus can reduce the contaminants adhered to the wafer. However, such ion implanter only traps the contaminants that have been diffused into the vacuum chamber and does not suppress the contaminants from diffusing into the vacuum chamber.

### SUMMARY

One embodiment of the ion beam irradiation apparatus comprises: an ion source, a mass spectrometer, and a vacuum vessel having an internal space where an ion beam taken out from the ion source pass in the first direction, wherein, the vacuum vessel has a recess that brings the internal space extending in a second direction intersecting the first direction in a portion of the area between the ion source and the mass spectrometer.

In addition, in the ion beam irradiation apparatus of one embodiment, the ion beam irradiation apparatus is further provided with a blocking member that hides a portion of the area of the recess from the ion beam in the internal space.

In addition, in one embodiment of the ion beam irradiation apparatus, the blocking member is a liner mounted to the inner wall of the vacuum vessel.

In addition, in one embodiment of the ion beam irradiation apparatus, the inner wall surface of the recess is treated with surface-roughen process.

In addition, in one embodiment of the ion beam irradiation apparatus, it further includes a recess liner disposed on the inner wall of the recess.

In addition, in one embodiment of the ion beam irradiation apparatus, it further includes a net-like member covering the recess

In addition, in one embodiment of the ion beam irradiation apparatus, it further includes a cooling apparatus that cools the recess.

In addition, in one embodiment of the ion beam irradiation apparatus, the cooling apparatus brings cooling water to flow through a pipe formed in a wall portion that forms the recess.

In addition, in one embodiment of the ion beam irradiation apparatus, the cooling apparatus has a cooling plate with cooling water flows inside, and the cooling plate is disposed outside the wall portion that forms the recess.

In addition, in one embodiment of the ion beam irradiation apparatus, the blocking member comprises a first blocking member and a second blocking member disposed apart from each other in the first direction.

In addition, one embodiment of the ion beam irradiation apparatus further includes a gate valve that has a plate-shaped valve body, and the valve body is configured to operate between a first closing member and a second closing member.

In addition, in one embodiments of the ion beam irradiation apparatus, the vacuum vessel includes a main body member having an opening that opens in the second direction, and a box-shaped member that is detachably mounted to the main body member so as to block the opening, and the recess is formed by mounting the box-shaped member to the main body member.

### BRIEF DESCRIPTION OF THE DRAWINGS

The above and/or other aspects will become apparent and more readily appreciated from the following description of embodiments, taken in conjunction with the accompanying drawings, of which:

FIG. 1 is a plan view schematically showing an ion beam irradiation apparatus according to an embodiment of the present invention.

FIG. 2 is a cross-sectional view showing a vacuum vessel according to the same embodiment.

FIG. 3 is a cross-sectional view taken from the C-C line shown in FIG. 2.

FIG. 4 is a cross-sectional view showing a modified example of the vacuum vessel.

### DETAILED DESCRIPTION

Generally, an ion beam irradiator includes an ion source that generates plasma from a raw material gas, and a vacuum chamber that forms a beam path through which an ion beam drawn from the plasma passes. In the conventional ion beam irradiation apparatus, when a part of the raw material gas introduced into the ion source flows into the vacuum chamber, the raw material gas is condensed on the inner wall surface of the vacuum chamber. As a result, deposits were formed on the inner wall surface of the vacuum chamber. This is because the temperature of the inner wall forming the vacuum chamber is lower than the temperature of the ion source at the time of plasma generation.

Furthermore, since the material forming the inner wall of the vacuum chamber and the deposit have different linear expansion coefficients, the deposit peels off from the inner wall of the vacuum chamber when the temperature in the vacuum chamber repeatedly changes due to repeated operation and stop of the device. That is, in the conventional ion beam irradiation apparatus, the deposits are peeled off from the inner wall of the vacuum vessel due to repeated operation and stop of the device, and the peeled-off deposits have been diffused in the vacuum chamber by the potential of the ion beam. In this way, in the conventional ion beam irradiation apparatus, there is a problem that the deposits deposited on the inner wall of the vacuum vessel are eventually diffused into the vacuum vessel.

One of the advantages of the ion beam irradiation apparatus of the present disclosure is that the deposits in the vacuum vessel can be suppressed from being diffused into the vacuum vessel.

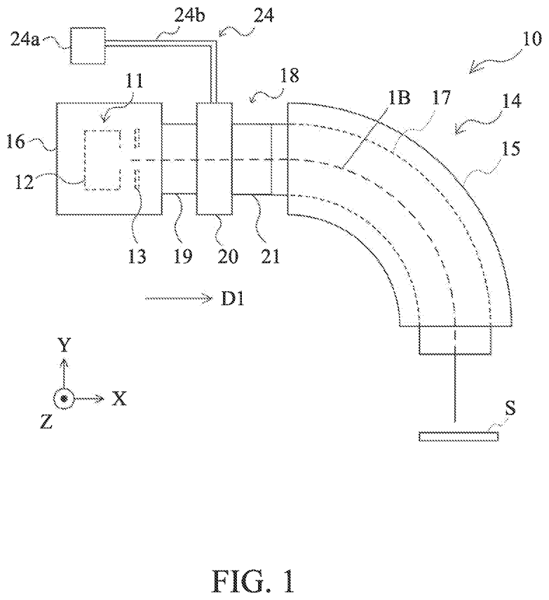

As shown in FIG. 1, the ion beam irradiation apparatus 10 according to the embodiment of the present disclosure is a device that irradiates an ion beam IB containing desired ions to the substrate S. The ion beam irradiation apparatus 10 is used in a semiconductor manufacturing process or the like, and is an ion implantation device for irradiating an ion beam IB to a substrate S, which is a semiconductor wafer, so as to perform an ion implantation process. The application of the ion beam irradiation apparatus 10 is not limited to this. For example, the ion beam irradiation apparatus 10 may be an ion implantation device used in the flat panel display manufacturing process. In this case, the substrate S may be a glass substrate.

As shown in FIG. 1, the ion beam irradiation apparatus 10 includes an ion source 11 for generating an ion beam IB, and a mass spectrometer 14. The mass spectrometer 14 has a magnet 15 that generates a magnetic field inside the mass spectrometer 14. The mass spectrometer 14 deflects the ion beam IB by the magnetic field generated by the magnet 15 to allow desired ions to pass.

As shown in FIG. 1, the ion source 11 includes a plasma chamber 12 in which plasma is generated. The ion source 11 generates a plasma containing desired ions from the raw material gas supplied to the plasma chamber 12. In addition, near the outside of the plasma chamber 12, an extraction electrode 13 for extracting ions contained in the plasma generated in the plasma chamber 12 as an ion beam IB is disposed. Also, the ion source 11, the extraction electrode 13, and the mass spectrometer 14 in the present embodiment all have a configuration generally used for an ion implantation device. The ion beam IB in the present embodiment has a predetermined length along the height direction of the ion source 11, that is, the Z direction in the drawing, and has a beam shape that is called a ribbon beam or a sheet beam. Also, the shape of the ion beam IB is not limited to this.

In addition, the ion beam irradiation apparatus 10 includes an ion source chamber 16 that accommodates inside the ion source 11 and a mass spectrometry chamber 17 that is arranged inside the mass spectrometer 14.

As shown in FIG. 1, the ion beam irradiation apparatus 10 further includes a vacuum vessel 18 arranged between the ion source chamber 16 and the mass spectrometry chamber 17. The vacuum vessel 18 has an internal space R that allows the ion beam IB taken out from the ion source 11 to pass in the first direction D1. The internal space R is connected to each of the internal space of the ion source chamber 16 and the internal space of the mass spectrometry chamber 17. The inside of the vacuum vessel 18 is put into a high vacuum state during the operation of the ion beam irradiation apparatus 10. In FIGS. 1 to 4, the first direction D1 coincides with the X direction, and the height direction of the vacuum vessel 18 coincides with the Z direction.

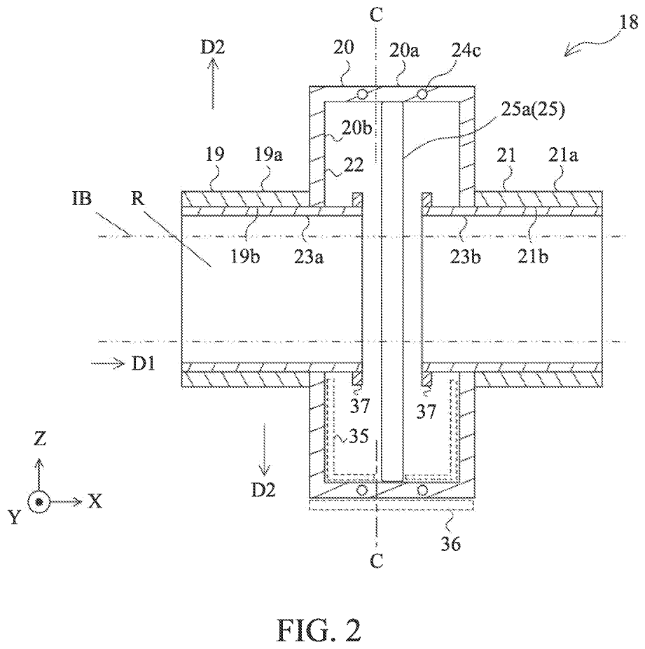

As shown in FIGS. 1 and 2, the vacuum vessel 18 in the present embodiment is constructed by arranging a first vessel 19, a second vessel 20, and a third vessel 21 in the first direction D1 and connecting these vessels. As shown in FIG. 2, the first vessel 19 has a first wall portion 19a that has a first inner wall surface 19b. The second vessel 20 has a second wall portion 20a that has a second inner wall surface 20b. The third vessel 21 has a third wall portion 21a that has a third inner wall surface 21b. The internal space R of the vacuum vessel 18 is a space formed by the first inner wall surface 19b, the second inner wall surface 20b, and the third inner wall surface 21b, and opens in the first direction D1. In addition, the above configuration of the vacuum vessel 18 is only an example. In the present embodiment, the vacuum vessel 18 may be configured to connect two vessels or four or more vessels. In addition, the vacuum vessel 18 may only comprise one vessel.

As shown in FIG. 2, the second wall portion 20a of the second vessel 20 is formed so that the cross section has a concave shape. The second vessel 20 has a recess 22 formed by the second inner wall surface 20b. The recess 22 bring the internal space R extended in a second direction D2 intersecting the first direction D1 which is the traveling direction of the ion beam IB. That is, the vacuum vessel 18 in the present embodiment has a recess 22 that brings the internal space R to expand in a second direction D2 intersecting the first direction D1 which is the traveling direction of the ion beam IB in the area between the ion source 11 and the mass spectrometer 14.

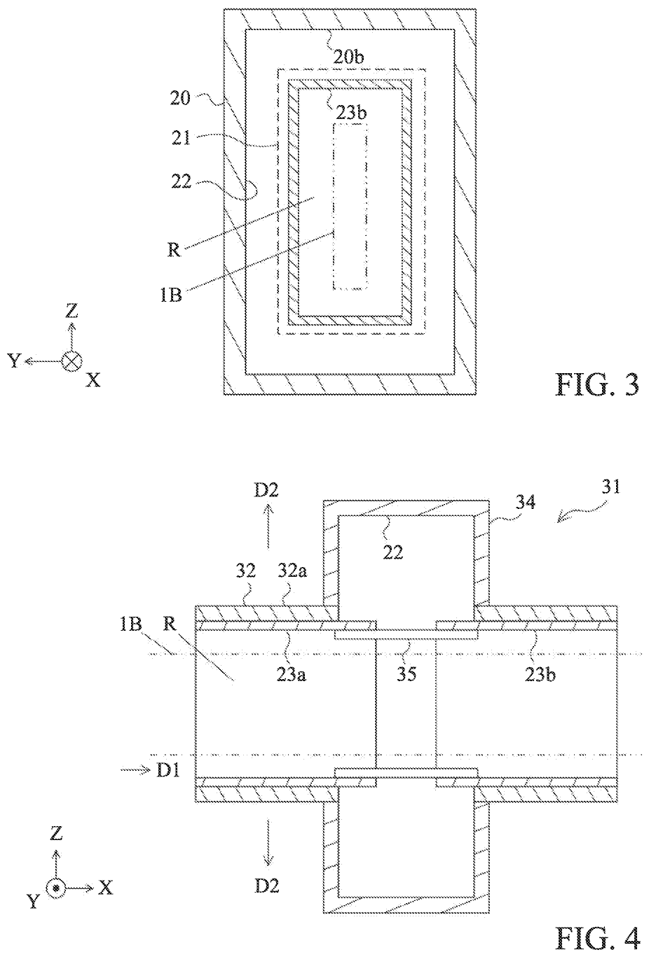

As shown in FIG. 3, in the present embodiment, the recess 22 is formed so as to surround the entire periphery of the ion beam IB traveling in the first direction D1. That is, the second direction D2 does not mean a specific direction, but indicates an arbitrary direction intersecting the first direction D1. In addition, the recess 22 is not limited to being formed so as to surround the entire periphery of the ion beam IB traveling in the first direction D1. That is, the recess 22 may be formed in a part of the area that surrounds the ion beam IB traveling in the first direction D1.

In addition, in the present embodiment, the recess 22 is formed so that the first direction D1 and the second direction D2 are orthogonal to each other, but the first direction D1 and the second direction D2 are not necessarily be orthogonal to each other. The recess 22 may form a space in the internal space R so as to be apart from the ion beam IB in a part of the area between the ion source 11 and the mass spectrometer 14.

As shown in FIG. 2, the ion beam irradiation apparatus 10 further includes a first blocking member 23a and a second blocking member 23b that hides a part of the recess 22 from the ion beam IB in the internal space R of the vacuum vessel 18. The first blocking member 23a is made of a carbon material, and is disposed on the first inner wall surface 19b of the first vessel 19 so as to cover the entire area of the first inner wall surface 19b and a portion of the area of the recess 22. Similarly, the second blocking member 23b is formed of a carbon material, and is disposed on the third inner wall surface 21b of the third vessel 21 so as to cover the entire area of the third inner wall surface 21b and a portion of the area of the recess 22. Both the first blocking member 23a and the second blocking member 23b also function as liner members for the vacuum vessel 18. Also, the first blocking member 23a and the second blocking member 23b may be formed of a member different from the liner member, and the blocking member in the present invention is not limited to also serving as the liner member.

The inner wall surface of the recess 22, that is, the second inner wall surface 20b, is treated with surface-roughen process. By increasing the roughness of the second inner wall surface 20b in this way, even if the gas or the like leaking from the ion source is condensed and deposited in the recess 22, due to the anchor effect, the deposits become difficult to peel off from the wall surface 20b.

In addition, instead of treating surface-roughen process on the second inner wall surface 20b, as shown by the dashed line in FIG. 2, a recess liner 35 made of carbon or metal may be disposed on the inner wall surface of the recess 22, i.e., the second inner wall surface 20b. Even in such case, grooves and irregularities may be formed in the recess liner 35 disposed on the inner wall surface of the recess 22, so that the deposits deposited on the second inner wall surface 20b are hard to peel off.

As shown in FIG. 1, the ion beam irradiation apparatus 10 includes a cooling apparatus 24 that cools the recess 22. The cooling apparatus 24 in the present embodiment cools the recess 22 by the cooling water, and includes a supply source 24a for supplying the cooling water and a pipe 24b through which the cooling water flows. The pipe 24b is connected to the hole portion 24c formed in the second wall portion 20a shown in FIG. 2. The recess 22 is cooled by the flow of cooling water through the hole 24c. Also, the above configuration is only an example of the cooling apparatus 24. For example, the cooling apparatus 24 may be configured to include a cooling plate 36 with cooling water flows inside, as shown by a dashed line in FIG. 2. In this case, the recess 22 can be cooled by arranging the cooling plate so as to be in contact with the outside of the second wall portion 20a. Also, the cooling apparatus 24 is not necessarily always required.

The vacuum vessel 18 in the present embodiment includes a recess 22 that expands the internal space R of the vacuum vessel 18 in a second direction D2 intersecting the first direction D1 in which the ion beam IB passes, in the second vessel 20 disposed between the ion source 11 and the mass spectrometer 14.

The area formed by the recess 22 of the internal space R is separated from the ion beam IB passing through the internal space R in the second direction D2 as compared with other areas. Therefore, the area formed by the recess 22 of the internal space R is less susceptible to the influence of radiant heat from the ion beam IB than the other areas, and the temperature is less likely to rise. That is, the area of the vacuum vessel 18 in which the recess 22 is formed has a lower temperature than the other areas.

When a gas such as a raw material gas is released from the ion source 11 and flows into the vacuum vessel 18, since the area where the recess 22 is formed is lower in temperature than the other areas, the gas is easy to condense on the inner wall surface of the recess 22. That is, the gas flowed into the vacuum vessel 18 is likely to condense on the second inner wall surface 20b that forms the recess 22. Therefore, when operating the ion beam irradiation apparatus 10 of the present embodiment, the deposits, which are generated by the condensation of the gas flowing from the ion source, adhere over time on the second inner wall surface 20b forming the recess 22. Since the deposits deposited in the recess 22 are deposited at a position farther from the ion beam IB as compared with other areas, the attraction by the potential of the ion beam IB is suppressed. As a result, the deposit is suppressed from peeling off from the recess 22 and diffused.

As shown in FIG. 2, the ion beam irradiation apparatus 10 of the present embodiment further includes a first blocking member 23a and a second blocking member 23b that hide a portion of the area of the recess 22 from the ion beam IB in the internal space R.

The ion beam irradiation apparatus 10 reduces the proportion of deposits on which the beam potential of the ion beam IB acts, by condensing the raw material gas in the recess 22 having a lower temperature than the other areas and hiding a part of the area of the recess 22 from the ion beam IB by the first blocking member 23a and the second blocking member 23b. As a result, the deposit can be locally accumulated in the recess 22, and the diffusion of the deposit into the internal space R is suppressed. In addition, even in the case that a part of the deposit in the recess 22 is attracted by the potential of the ion beam IB, the movement is restricted by the first block member 23a or the second block member 23b, and the diffusion of the deposit to the internal space R is hindered. As a result, the deposits in the vacuum vessel are suppressed from being diffused into the vacuum vessel, and the contaminants adhering to the substrate S are reduced.

In addition, in the ion beam irradiation apparatus of the present invention, the first blocking member 23a and the second blocking member 23b also serve as liners mounted to the first inner wall surface 19b and the third inner wall surface 21b that form the inner wall surface of the vacuum vessel 18. Therefore, the number of parts can be reduced and the configuration can be simplified.

In addition, the ion beam irradiation apparatus 10 is disposed between the ion source chamber 16 and the mass spectrometry chamber 17, and includes a gate valve 25 having a plate-shaped valve body 25a. By providing the gate valve 25, the ion beam irradiation apparatus 10 allows maintenance work and the like by opening the ion source chamber 16 to the atmosphere while keeping the inside of the mass spectrometry chamber 17 at a high vacuum.

As shown in FIG. 2, the valve body 25a is disposed so as to pass between the first blocking member 23a and the second blocking member 23b in the first direction D1. That is, the first blocking member 23a and the second blocking member 23b are separated from each other by a predetermined interval in the first direction D1, so as to enable the valve body 25a to operate.

Next, the vacuum vessel 31 which is a modified example of the vacuum vessel 18 in the ion beam irradiation apparatus 10 in the present embodiment will be described. Also, the same components as those of the vacuum vessel 18 are denoted by the same reference numerals in FIG. 4, and the description thereof will be omitted.

As shown in FIG. 4, the vacuum vessel 31 includes a main body member 32 that has a wall portion 32a forming the internal space R. An opening 33 that opens in the thickness direction of the wall portion 32a is formed in a part of the area of the wall portion 32a.

In addition, the vacuum vessel 31 includes a box-shaped member 34 detachably mounted to the main body member 32 so as to block the opening 33. In the vacuum vessel 31, the recess 22 is formed by mounting the box-shaped member 34 to the main body member 32. In this modified example, the box-shaped member 34 is formed by combining a plurality of plate materials and the like.

According to this modified example, the box-shaped member 34 is detachably mounted to the main body member 32, and the box-shaped member 34 can be detached from the main body member 32 so as to perform maintenance work. Therefore, maintenance work such as cleaning becomes easy.

As shown in FIG. 4, a net-like member 35 formed of a carbon material in a net-like shape is disposed between the first blocking member 23a and the second blocking member 23b. The net-like member 35 restrings the diffusion of the deposit into the internal space R when the deposit is peeled off from the recess 22. The net-like member 35 may be arranged so as to cover the recess 22, and is not limited to the configuration of the present embodiment. In addition, for example, it is not necessary to arrange the first blocking member 23a or the second blocking member 23b to be parallel to the first direction D1. In addition, a protruding portion 37 extending in a direction intersecting the first direction may be further formed at each end of the first blocking member 23a and the second blocking member 23b facing each other. In this case, the formation of the protruding portion 37 restrings the diffusion to the ion source chamber 16 side or the mass spectrometry chamber 17 side even if the deposit is peeled off from the recess 22,

It is to be understood that the present disclosure is not limited to the above embodiments, but various changes and modifications may be made therein without departing from the spirit and scope thereof as set forth in appended claims.

What is claimed is:

1. An ion beam irradiation apparatus, comprising: an ion source, a mass spectrometer, and a vacuum vessel having an internal space where an ion beam taken out from the ion source pass in the first direction,
wherein, the vacuum vessel has a recess that brings the internal space extended in a second direction intersecting the first direction in a portion of the area between the ion source and the mass spectrometer.

2. The ion beam irradiation apparatus according to claim 1, further comprising a blocking member that hides a portion of the area of the recess from the ion beam in the internal space.

3. The ion beam irradiation apparatus according to claim 2, wherein the blocking member is a liner mounted to the inner wall of the vacuum vessel.

4. The ion beam irradiation apparatus according to claim 1, wherein the inner wall surface of the recess is treaded with surface-roughen process.

5. The ion beam irradiation apparatus according to claim 1, further comprising a recess liner disposed on the inner wall of the recess.

6. The ion beam irradiation apparatus according to claim 1, further comprising a net-like member covering the recess.

7. The ion beam irradiation apparatus according to claim 1, further comprising a cooling apparatus that cools the recess.

8. The ion beam irradiation apparatus according to claim 7, wherein the cooling apparatus brings cooling water to flow through a pipe formed in a wall portion that forms the recess.

9. The ion beam irradiation apparatus according to claim 7, wherein the cooling apparatus has a cooling plate with cooling water flows inside, and
the cooling plate is disposed outside the wall portion that forms the recess.

10. The ion beam irradiation apparatus according to claim 1, wherein the blocking member comprises a first blocking member and a second blocking member disposed apart from each other in the first direction.

11. The ion beam irradiation apparatus according to claim 10, further comprising a gate valve that has a plate-shaped valve body,
wherein the valve body is configured to operate between the first blocking member and the second blocking member.

12. The ion beam irradiation apparatus according to claim 1, wherein the vacuum vessel includes a main body member having an opening that opens in the second direction, and a box-shaped member that is detachably mounted to the main body member so as to block the opening, and
the recess is formed by mounting the box-shaped member to the main body member.
